(19) United States
(12) Patent Application Publication
(10) Pub. No.: US 2025/0248237 A1
(43) Pub. Date: Jul. 31, 2025

(54) DISPLAY SUBSTRATE AND DISPLAY APPARATUS

(71) Applicants: Yunnan Invensight Optoelectronics Technology Co., Ltd., Yunnan (CN); BOE Technology Group Co., Ltd., Beijing (CN)

(72) Inventors: Chao Pu, Beijing (CN); Dacheng Zhang, Beijing (CN); Qingshan Shan, Beijing (CN); Xiaochuan Chen, Beijing (CN); Yinhu Huang, Beijing (CN); Shengji Yang, Beijing (CN); Pengcheng Lu, Beijing (CN); Zhao Ma, Beijing (CN); Yingbing Zhang, Beijing (CN); Liuzeming Qu, Beijing (CN); Qi Su, Beijing (CN); Zhuoyang Xie, Beijing (CN)

(21) Appl. No.: 18/838,487

(22) PCT Filed: Oct. 25, 2023
(86) PCT No.: PCT/CN2023/126336

§ 371 Date: Aug. 14, 2024

(51) Int. Cl. H10K 59/126; H10K 59/121; H10K 59/131

(52) U.S. Cl. CPC H10K 59/126; H10K 59/1213; H10K 59/131

(57) ABSTRACT

A display substrate and a display apparatus are provided. The display substrate includes: a silicon-based base substrate including an active area and an edge area; a plurality of sub-pixels in the active area, where at least one sub-pixel includes a pixel driving circuit including a first transistor including a semiconductor layer, a gate, a source, and a drain; an electronic device in the edge area including a second transistor including a semiconductor layer, a gate, a source and a drain which are arranged in same layers as the semiconductor layer, the gate, the source and the drain of the first transistor, respectively; and a metal shielding portion in the edge area arranged in a fragmented manner on a side of each of the layers in which the semiconductor layer, the gate, the source and the drain of the second transistor are respectively located away from the silicon-based base substrate, and orthographic projections of the metal shielding portion and the electronic device on the silicon-based base substrate overlap at least partially.

### TECHNICAL FIELD

The present disclosure relates to a field of display technology, and in particular to a display substrate and a display apparatus.

### BACKGROUND

With the continuous development of display technology, silicon-based organic light-emitting diode (OLED) display products have attracted widespread attention due to their advantages such as high resolution, low power consumption, small dimension and light weight. They have good application prospects in high-resolution near-eye display industries such as wearable devices, industrial security, and medical industry. In order to improve a display effect of the silicon-based OLEDs, an OTP (one time programmable) is usually applied to the silicon-based OLEDs to compensate for pixel units. However, in a manufacturing process of the silicon-based OLEDs, the OTP for the silicon-based OLEDs is easily affected by energy radiation in an ion sputtering coating process and UV irradiation in a curing process, resulting in an OTP failure, which ultimately leads to a display abnormality or a black screen of the silicon-based OLEDs, seriously affecting the product yield.

How to provide protection to the OTP for the silicon-based OLEDs so as to shield the OTP from the energy radiation and the UV irradiation in the manufacturing process, ensure stability of an OTP programming state and improve the product yield is one of the important research topics for R&D personnel.

The above information disclosed in this section is only for understanding the background of the technical concept of the present disclosure and therefore the above information may contain information that does not constitute the prior art.

### SUMMARY

In an aspect, a display substrate is provided. The display substrate includes: a silicon-based base substrate including an active area and an edge area surrounding the active area; a plurality of sub-pixels in the active area of the silicon-based base substrate, wherein the plurality of sub-pixels are arranged in an array in a first direction and a second direction, at least one of the plurality of sub-pixels includes a pixel driving circuit and a light-emitting element, the pixel driving circuit is electrically connected to the light-emitting element and configured to drive the light-emitting element to emit light, and wherein the pixel driving circuit includes a first transistor, the first transistor includes a semiconductor layer, a gate, a source, and a drain; an electronic device in the edge area of the silicon-based base substrate, wherein the electronic device includes a second transistor, the second transistor includes a semiconductor layer, a gate, a source and a drain, and the semiconductor layer, the gate, the source and the drain of the second transistor are arranged in same layers as the semiconductor layer, the gate, the source and the drain of the first transistor, respectively; and a metal shielding portion in the edge area of the silicon-based base substrate, wherein the metal shielding portion is arranged in a fragmented manner on a side of each of the layers in which the semiconductor layer, the gate, the source and the drain of the second transistor are respectively located away from the silicon-based base substrate, wherein an orthographic projection of the metal shielding portion on the silicon-based base substrate at least partially overlaps with an orthographic projection of the electronic device on the silicon-based base substrate.

According to some exemplary embodiments, the orthographic projection of the metal shielding portion on the silicon-based base substrate covers the orthographic projection of the electronic device on the silicon-based base substrate.

According to some exemplary embodiments, the display substrate further includes n metal film layers, wherein the n metal film layers are arranged on a side of the layer in which the source of the electronic device and the drain of the electronic device are located away from the silicon-based base substrate, the n metal film layers are sequentially arranged away from the silicon-based base substrate, and n is a positive integer greater than or equal to 2; and wherein the metal shielding portion includes n metal shielding sub-portions, and the n metal shielding sub-portions are arranged in the n metal film layers, respectively.

According to some exemplary embodiments, the display substrate further includes n conductive connection portions located in the active area, wherein the n conductive connection portions are arranged in the n metal film layers, respectively, and each of the n metal shielding sub-portions is arranged in a same metal film layer as a respective one of the n conductive connection portions.

According to some exemplary embodiments, the metal shielding portion includes a plurality of metal shielding sub-portions arranged in a same metal film layer, and any two adjacent metal shielding sub-portions among the plurality of metal shielding sub-portions arranged in the same metal film layer are spaced apart from each other.

According to some exemplary embodiments, an orthographic projection of the n metal shielding sub-portions on the silicon-based base substrate at least partially overlap with an orthographic projection of a same electronic device on the silicon-based base substrate; and wherein an orthographic projection of one of any two of the n metal shielding sub-portions on the silicon-based base substrate coincides with an orthographic projection of the other of the any two of the n metal shielding sub-portions on the silicon-based base substrate.

According to some exemplary embodiments, orthographic projections of at least two of the n metal shielding sub-portions on the silicon-based base substrate at least do not partially overlap with each other.

According to some exemplary embodiments, the n metal shielding sub-portions include: a plurality of first metal shielding sub-portions arranged in an i^{th} metal film layer; and a plurality of second metal shielding sub-portions arranged in an (i+1)^{th} metal film layer, wherein i is a positive integer greater than or equal to 1 and less than or equal to (n−2); and wherein orthographic projections of the plurality of first metal shielding sub-portions on the silicon-based base substrate and orthographic projections of the plurality of second metal shielding sub-portions on the silicon-based base substrate are alternately arranged in the first direction.

According to some exemplary embodiments, the n metal shielding sub-portions further include a plurality of third metal shielding sub-portions arranged in an (i+2)^{th} metal film layer; and wherein orthographic projections of the plurality of third metal shielding sub-portions on the silicon-based base substrate and the orthographic projections of the plurality of second metal shielding sub-portions on the silicon-based base substrate are alternately arranged in the first direction.

According to some exemplary embodiments, an orthographic projection of at least one of the plurality of second metal shielding sub-portions on the silicon-based base substrate partially overlaps with an orthographic projection of an adjacent first metal shielding sub-portion among the plurality of first metal shielding sub-portions on the silicon-based base substrate or an orthographic projection of an adjacent third metal shielding sub-portion among the plurality of third metal shielding sub-portions on the silicon-based base substrate.

According to some exemplary embodiments, the orthographic projections of the plurality of first metal shielding sub-portions on the silicon-based base substrate coincide with the orthographic projections of the plurality of third metal shielding sub-portions on the silicon-based base substrate, respectively.

According to some exemplary embodiments, the display substrate includes m electronic devices and m metal shielding portions, where m is a positive integer greater than or equal to 2; and orthographic projections of the m metal shielding portions on the silicon-based base substrate cover orthographic projections of the m electronic devices on the silicon-based base substrate, respectively.

According to some exemplary embodiments, orthographic projections of at least two adjacent metal shielding portions among the m metal shielding portions on the silicon-based base substrate are arranged at intervals in the first direction.

According to some exemplary embodiments, orthographic projections of any two adjacent metal shielding portions among the m metal shielding portions on the silicon-based base substrate at least partially overlap with each other, such that the orthographic projections of the m metal shielding portions on the silicon-based base substrate extend continuously in the first direction.

According to some exemplary embodiments, at least two of the n metal shielding sub-portions have different thicknesses; or the n metal shielding sub-portions have a same thickness.

According to some exemplary embodiments, among the n metal shielding sub-portions and the n conductive connection portions, the metal shielding sub-portion and the conductive connection portion arranged in the same metal film layer have a same thickness.

According to some exemplary embodiments, the display substrate further includes a plurality of bonding terminals arranged in the edge area of the silicon-based base substrate, where the orthographic projection of the metal shielding portion on the silicon-based base substrate is located between orthographic projections of the plurality of bonding terminals on the silicon-based base substrate and the active area.

According to some exemplary embodiments, the metal shielding portion includes a plurality of metal shielding sub-portions arranged in a same metal film layer as the plurality of bonding terminals, and a dimension of each of the plurality of metal shielding sub-portions arranged in the same metal film layer as the plurality of bonding terminals in the first direction is substantially equal to a dimension of a respective one of the plurality of bonding terminals in the first direction; and/or a dimension of a gap between any two of the plurality of metal shielding sub-portions arranged in the same metal film layer as the plurality of bonding terminals in the first direction is substantially equal to a dimension of a gap between any two of the plurality of bonding terminals in the first direction; and/or a dimension of each of the plurality of metal shielding sub-portions arranged in the same metal film layer as the plurality of bonding terminals in the second direction is less than a dimension of a respective one of the plurality of bonding terminals in the second direction.

According to some exemplary embodiments, at least one of the plurality of sub-pixels further includes a reflective electrode, and a film layer in which the reflective electrode is located is arranged between a film layer in which the pixel driving circuit is located and a film layer in which the light-emitting element is located; wherein the metal shielding portion further includes a plurality of top-layer metal shielding sub-portions arranged in a same layer as the reflective electrode; and wherein a dimension of each of the plurality of top-layer metal shielding sub-portions in the first direction is substantially equal to a dimension of a respective one of a plurality of reflective electrodes in the first direction; and/or a dimension of a gap between any two of the plurality of top-layer metal shielding sub-portions in the first direction is substantially equal to a dimension of a gap between any two of a plurality of reflective electrodes in the first direction.

According to some exemplary embodiments, the (i+1)^{th} metal film layer is arranged on a side of the i^{th} metal film layer away from the silicon-based base substrate, and the (i+2)^{th} metal film layer is arranged on a side of the (i+1)^{th} metal film layer away from the silicon-based base substrate; and wherein an edge of the second metal shielding sub-portion is indented towards a center of an electronic device corresponding to the first metal shielding sub-portion and the second metal shielding sub-portion with respect to an edge of the first metal shielding sub-portion, and an edge of the third metal shielding sub-portion is indented towards a center of an electronic device corresponding to the second metal shielding sub-portion and the third metal shielding sub-portion with respect to an edge of the second metal shielding sub-portion.

According to some exemplary embodiments, a protrusion is provided at the edge of the first metal shielding sub-portion, such that a thickness of the first metal shielding sub-portion at the edge of the first metal shielding sub-portion is greater than a thickness of the first metal shielding sub-portion at a center of the first metal shielding sub-portion; and/or a protrusion is provided at the edge of the second metal shielding sub-portion, such that a thickness of the second metal shielding sub-portion at the edge of the second metal shielding sub-portion is greater than a thickness of the second metal shielding sub-portion at a center of the second metal shielding sub-portion n.

According to some exemplary embodiments, a cross-section of the protrusion perpendicular to an upper surface of the silicon-based base substrate and a cross-section of a conductive connection portion arranged in a same layer as the protrusion perpendicular to the upper surface of the silicon-based base substrate have a same shape.

According to some exemplary embodiments, the n metal shielding sub-portions further include a fourth metal shielding sub-portion arranged in a j^{th} metal film layer, and j is a positive integer greater than 1 and less than n; wherein the pixel driving circuit further includes a capacitor, at least one electrode plate of the capacitor is arranged in the j^{th} metal film layer; and wherein a thickness of the fourth metal shield sub-portion is less than a thickness of any one of the first metal shield sub-portion, the second metal shield sub-portion, and the third metal shield sub-portion.

According to some exemplary embodiments, the electronic device includes a memory cell, and the memory cell includes a pair of transistors arranged on the silicon-based base substrate and electrically connected to each other in series; and wherein the orthographic projection of the metal shielding portion on the silicon-based base substrate covers orthographic projections of the pair of transistors on the silicon-based base substrate.

According to some exemplary embodiments, a sum of thicknesses of the n metal shielding sub-portions meets:

$$H \geq \sqrt{\frac{2}{ω μ σ}} ,$$

where δ and ω are respectively a penetration depth and a frequency of radiation rays irradiated on the metal shielding portion, μ and σ are respectively a magnetic conductivity of the metal shielding portion and an electrical conductivity of the metal shielding portion, and His the sum of the thicknesses of the n metal shielding sub-portions.

In another aspect, a display apparatus is provided. The display apparatus includes any display substrate described above.

### BRIEF DESCRIPTION OF THE DRAWINGS

The above and other objectives, features and advantages of the present disclosure will become more clear through the following description of embodiments of the present disclosure with reference to the accompanying drawings, in which:

FIG. 1 shows a schematic diagram of a layout of display substrates on a silicon wafer according to an embodiment of the present disclosure;

FIG. 2 shows a schematic diagram of each functional area of a display substrate according to an embodiment of the present disclosure;

FIG. 3 shows a partial enlarged schematic cross-sectional view of a sub-pixel of the display substrate taken along line CC′ shown in FIG. 2 according to some embodiments of the present disclosure;

FIG. 4 shows a partial enlarged schematic cross-sectional view of the display substrate taken along line BB′ shown in FIG. 2 according to some exemplary embodiments of the present disclosure, in which a correspondence between film layers of a first transistor arranged in the active area AA and film layers of a second transistor arranged in the edge area EA is shown;

FIG. 5 shows a schematic cross-sectional view of a single electronic device OTP in the display substrate taken along line DD′ shown in FIG. 2 according to some embodiments of the present disclosure;

FIG. 6 shows an equivalent circuit diagram of the electronic device OTP shown in FIG. 5;

FIG. 7 shows a schematic diagram of charge loss on a floating gate FG in an OTP of a display substrate according to some embodiments of the present disclosure;

FIG. 8 shows a partial schematic cross-sectional view of an OTP area of the display substrate taken along line DD′ shown in FIG. 2 according to some other embodiments of the present disclosure, in which a metal shielding portion is shown;

FIG. 9 shows a partial schematic cross-sectional view of an OTP area of the display substrate taken along line DD′ shown in FIG. 2 according to some other embodiments of the present disclosure;

FIG. 10 shows a partial schematic cross-sectional view of the display substrate taken along line B-B′ shown in FIG. 2 according to some embodiments of the present disclosure, in which a relationship of correspondence between film layers of metal film layers in a active area and film layers of a metal shielding portion in a edge area is shown;

FIG. 11 shows a partial schematic cross-sectional view of an OTP area of the display substrate taken along line DD′ shown in FIG. 2 according to some other embodiments of the present disclosure;

FIG. 12 shows a partial schematic cross-sectional view of an OTP area of the display substrate taken along line DD′ shown in FIG. 2 according to some other embodiments of the present disclosure;

FIG. 13A and FIG. 13B show schematic plan views of an OTP area of a display substrate according to some embodiments of the present disclosure;

FIG. 14 shows a schematic plan view of metal shielding portions and bonding terminals of a display substrate according to some other embodiments of the present disclosure;

FIG. 15 shows a schematic plan view of a top-layer metal shielding sub-portion and a reflective electrode of a display substrate according to some other embodiments of the present disclosure;

FIG. 16 shows a schematic structural diagram of a metal shielding layer corresponding to a single OTP according to some embodiments of the present disclosure;

FIG. 17 shows a partial schematic cross-sectional view of the display substrate taken along line BB′ shown in FIG. 2 according to some exemplary embodiments of the present disclosure, in which a metal shielding sub-portion and a conductive connection portion arranged in a same layer are shown;

FIG. 18 shows a schematic structural diagram of a metal shielding layer corresponding to a single OTP according to some other embodiments of the present disclosure; and

FIG. 19 shows a schematic structural diagram of a display apparatus according to some embodiments of the present disclosure.

It should be noted that, for the sake of clarity, in the accompanying drawings used to describe embodiments of the present disclosure, dimensions of layers, structures or regions may be enlarged or reduced, that is, these drawings are not drawn according to the actual scale.

### DETAILED DESCRIPTION OF EMBODIMENTS

In order to make the objectives, technical solution and advantages of embodiments of the present disclosure clearer, the technical solution of the embodiments of the present disclosure will be clearly and completely described below in conjunction with the drawings of the embodiments of the present disclosure. Clearly, the described embodiments are only part of the embodiments of the present disclosure, rather than all the embodiments. Based on the described embodiments of the present disclosure, all other embodiments obtained by those of ordinary skill in the art without inventive labor are within the scope of protection of the present disclosure.

It should be noted that, for the sake of clarity and/or description, dimensions and relative dimensions of elements may be enlarged in the drawings. Thus, the dimensions and relative dimensions of the respective elements are not necessarily limited to the dimensions and relative dimensions shown in the drawings. In the specification and drawings, the same or similar reference numerals indicate the same or similar components.

Unless otherwise defined, technical or scientific terms used in the present disclosure should have the common meanings understood by one of ordinary skill in the art. The terms “first”, “second” and the like used in the present disclosure do not indicate any order, quantity or importance, but are only used to distinguish different components. The terms “include”, “comprise” or the like mean that the elements or objects preceding the word include the elements or objects listed after the word and their equivalents, but do not exclude other elements or objects.

In the present disclosure, unless otherwise specifically stated, directional terms such as “upper”, “lower”, “left”, “right”, “inner”, “outer”, etc. are used to indicate the orientation or positional relationship based on the drawings, and are only for ease of description of the present disclosure, but do not indicate or imply that the device, element or component referred to have to have a specific orientation, or be constructed or operate in a specific orientation. It should be understood that when the absolute positions of the described objects change, the relative positional relationships they represent may also change accordingly. Therefore, these directional terms should not be construed as limiting the present disclosure.

It should be noted that, in the present disclosure, the “same layer” refers to a layer structure formed by forming a film layer for forming a specific pattern using the same film forming process, and then patterning the film layer through a single patterning process using the same mask. Depending on the specific pattern, the patterning process may include a plurality of exposure, development or etching processes, and the specific pattern in the formed layer structure may be continuous or discontinuous. That is, the plurality of elements, components, structures and/or parts located in the “same layer” are composed of the same material and are formed by using the same patterning process. Generally, the plurality of elements, components, structures and/or parts located in the “same layer” have substantially the same thickness.

Those skilled in the art should understand that, in the present disclosure, unless otherwise specified, the expression “height” or “thickness” refers to a dimension of a surface of each film layer arranged perpendicular to the display substrate. That is, a dimension along the light output direction of the display substrate, or a dimension along the normal direction of the display device.

In the present disclosure, the directional expressions “first direction” and “second direction” are used to describe different directions along the pixel unit, for example, longitudinal and transverse directions of the pixel unit, or row and column directions in which the sub-pixels are arranged. It should be understood that such representations are merely exemplary descriptions and are not limitations to the present disclosure.

In the present disclosure, the expression “transistor” may refer to a triode, a thin film transistor, a field effect transistor or other devices with the same characteristics. In the embodiments of the present disclosure, in order to distinguish two electrodes of a transistor other than a control electrode of the transistor, one of the electrodes is called a first electrode and the other is called a second electrode. In actual operation, when the transistor is a thin film transistor or a field effect transistor, the first electrode may be a drain, and the second electrode may be a source; or, the first electrode may be a source, and the second electrode may be a drain.

Some exemplary embodiments of the present disclosure provide a display substrate. The display substrate includes: a silicon-based base substrate, including an active area and an edge area surrounding the active area; a plurality of sub-pixels in the active area of the silicon-based base substrate and arranged in an array in a first direction and a second direction, where at least one of the plurality of sub-pixels includes a pixel driving circuit and a light-emitting element, the pixel driving circuit is electrically connected to the light-emitting element and is used to drive the light-emitting element to emit light, and the pixel driving circuit includes a first transistor, the first transistor includes a semiconductor layer, a gate, a source, and a drain; an electronic device in the edge area of the silicon-based base substrate, the electronic device including a second transistor, where the second transistor includes a semiconductor layer, a gate, a source and a drain, and the semiconductor layer, the gate, the source and the drain of the second transistor are arranged in same layers as the semiconductor layer, the gate, the source and the drain of the first transistor, respectively; and a metal shielding portion in the edge area of the silicon-based base substrate, where the metal shielding portion is arranged in a fragmented manner on a side of each of the layers in which the semiconductor layer, the gate, the source and the drain of the second transistor are respectively located away from the silicon-based base substrate. An orthographic projection of the metal shielding portion on the silicon-based base substrate at least partially overlaps with an orthographic projection of the electronic device on the silicon-based base substrate. According to the display substrate provided in embodiments of the present disclosure, the metal shielding portion is arranged above the electronic device, so that it is possible to not only shield the electronic device from energy radiation and UV irradiation in a manufacturing process so as to maintain the stability of the electronic device, but also reduce the influence of reflection of the metal shielding portion on a display effect and provide a uniformity to the manufacturing process.

For example, in some exemplary embodiments of the present disclosure, the electronic device may be a one-time programmable device. In this way, by arranging the metal shielding portion above the one-time programmable electronic device, it is possible to shield the energy radiation and the UV irradiation to which the one-time programmable electronic device is subjected in the manufacturing process of silicon-based OLED, so that the stability of a programmable state of the electronic device may be maintained, thereby ensuring that the electronic device may effectively compensate for a voltage of a pixel unit and thus improving the uniformity of brightness of the display product, so as to further improve the display effect of the silicon-based OLED display product.

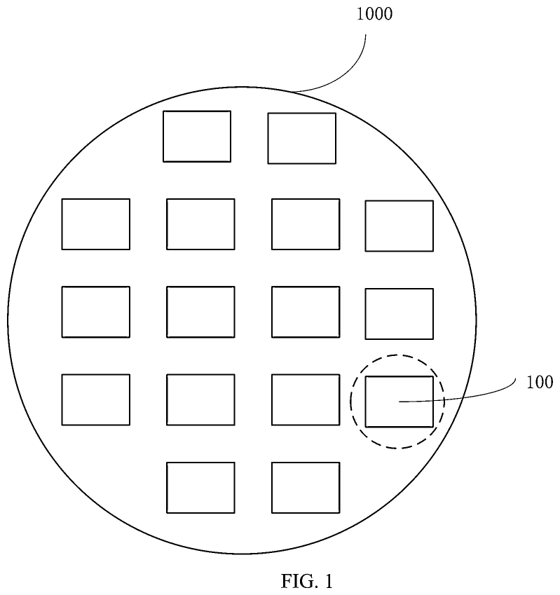

FIG. 1 shows a schematic diagram of a layout of display substrates on a silicon wafer according to an embodiment of the present disclosure, namely a wafer map. The wafer map schematically shows the number and an arrangement of display substrates 100 on a silicon wafer 1000. It may be understood that the number and the arrangement of the display substrates 100 shown in the figure are for illustrative purposes only and are not intended to limit the embodiments of the present disclosure.

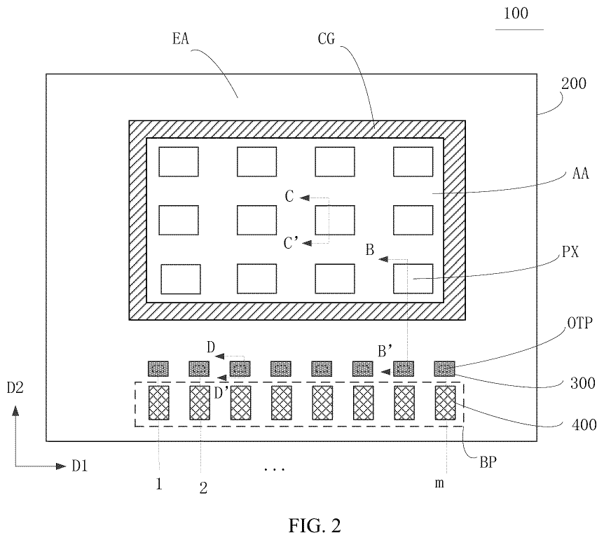

FIG. 2 shows a schematic diagram of each functional area of a display substrate according to an embodiment of the present disclosure.

In an example, in some embodiments of the present disclosure, referring to FIG. 2, the display substrate 100 includes: a silicon-based base substrate 200 including an active area (abbreviated as AA) and an edge area (abbreviated as EA) surrounding the active area AA; a plurality of pixel units PX in the active area AA of the silicon-based base substrate and arranged in an array in a first direction D1 and a second direction D2; a cover glass CG bonding adhesive area in the edge area EA of the silicon-based base substrate, closely surrounding the active area AA and used to arrange an encapsulation layer to seal and protect the active area AA; an electronic device in the edge area EA of the silicon-based base substrate, such as a one-time programmable device (abbreviated as OTP); and a metal shielding portion 300 in the edge area EA of the silicon-based base substrate. An orthographic projection of the metal shielding portion 300 on the silicon-based base substrate 200 at least partially overlaps with an orthographic projection of the electronic device OTP on the silicon-based base substrate 200. By providing the metal shielding portion, it is possible to reduce an impact of part of the radiation energy in an ion sputtering coating process or a UV curing process on the electronic device OTP in a manufacturing process of the silicon-based OLED display substrate, thereby improving the display effect of the display substrate.

In an example, the display substrate 100 further includes a bonding pad (BP) in the edge area EA of the silicon-based base substrate, a plurality of bonding terminals 400 are arranged in the bonding pad, and the plurality of bonding terminals 400 are used to provide channels for a signal input or a signal output to the display substrate.

In an example, with continued reference to FIG. 2, in some embodiments of the present disclosure, the orthographic projection of the metal shielding portion 300 on the silicon-based base substrate 200 is located between orthographic projections of the plurality of bonding terminals 400 on the silicon-based base substrate 200 and an orthographic projection of the active area AA on the silicon-based base substrate 200.

In embodiments of the present disclosure, the active area AA may have various shapes. For example, the active area AA may be arranged in various shapes, such as a closed-shape polygon (e.g., a rectangle) including straight sides, shapes including curved sides such as a circle and an ellipse, a semicircle including straight sides and curved sides, and a semi-ellipse including straight sides and curved sides. In embodiments of the present disclosure, the active area AA is arranged as an area in a shape of a quadrangle including straight sides. It should be understood that this is merely an exemplary embodiment of the present disclosure, rather than a limitation to the present disclosure.

The edge area EA may surround a periphery of the active area AA. In embodiments of the present disclosure, the edge area EA may include a lateral portion extending in the first direction D1 and a vertical portion extending in the second direction D2.

The pixel unit PX is arranged in the active area AA. The pixel unit PX is a minimum unit for displaying an image, and more than one pixel unit PX may be provided. For example, the pixel unit PX may include a light-emitting device that emits white light and/or color light.

The plurality of pixel unit PX may be provided and arranged in a matrix with rows extending in the first direction D1 and columns extending in the second direction D2. However, embodiments of the present disclosure do not particularly limit an arrangement form of the pixel units PX, and the pixel units PX may be arranged in various forms. For example, the pixel units PX may be arranged such that a direction inclined with respect to the first direction D1 and the second direction D2 serves as a column direction, and a direction intersecting with the column direction serves as a row direction.

The pixel unit PX may include a plurality of sub-pixels. For example, one pixel unit PX may include three sub-pixels, namely a first sub-pixel, a second sub-pixel, and a third sub-pixel. For another example, the pixel unit PX may include four sub-pixels, namely a first sub-pixel, a second sub-pixel, a third sub-pixel, and a fourth sub-pixel. For example, the first sub-pixel may be a red sub-pixel, the second sub-pixel may be a green sub-pixel, the third sub-pixel may be a blue sub-pixel, and the fourth sub-pixel may be a white sub-pixel. At least one sub-pixel may include a light-emitting element and a pixel driving circuit for driving the light-emitting element. The pixel driving circuit is electrically connected to a corresponding light-emitting element of the sub-pixel and may drive the light-emitting element of the sub-pixel to emit light of a corresponding color.

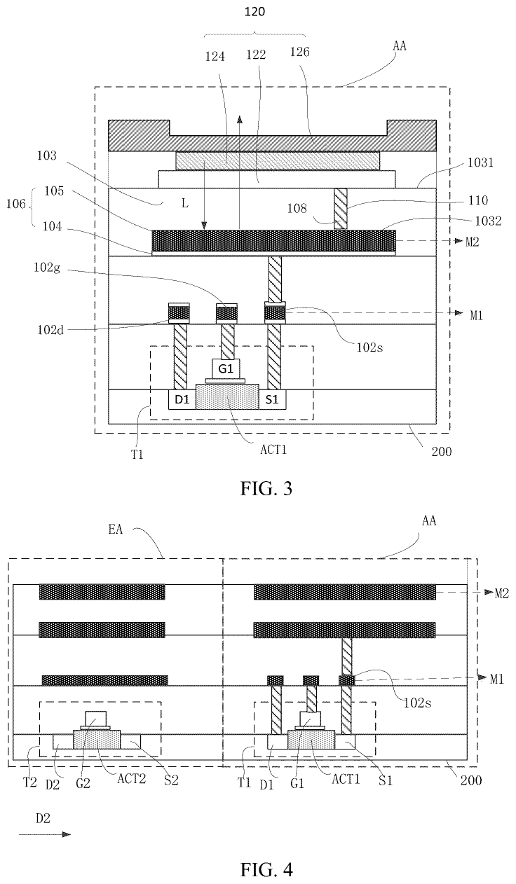

FIG. 3 shows a partial enlarged schematic cross-sectional view of a sub-pixel of the display substrate taken along line CC′ shown in FIG. 2 according to some embodiments of the present disclosure.

In an example, in some embodiments of the present disclosure, referring to FIG. 3, the display substrate includes a sub-pixel in the active area AA, the sub-pixel may include a reflective electrode 106 and a light-emitting element 120 on the reflective electrode 106, and the light-emitting element 120 includes a first electrode layer 122, an organic light-emitting functional layer 124 and a second electrode layer 126 sequentially stacked on the reflective electrode 106. The sub-pixel may further include an insulation layer 103 between the reflective electrode 106 and the first electrode layer 122. The insulation layer 103 is transparent so that light emitted by the organic light-emitting functional layer 124 passes through the insulation layer 103 and reaches the reflective electrode 106 to be reflected by the reflective electrode 106. The reflective electrode 106 and the first electrode layer 122 are spaced apart by the insulation layer 103. Thus, when the reflective electrode 106 is manufactured, the reflective electrode 106 may be integrated into a driving substrate manufactured in a wafer factory, thereby reducing the manufacturing cost of the reflective electrode 106 and the difficulty in manufacturing the reflective electrode 106. In addition, when the light L emitted by the organic light-emitting functional layer 124 is incident on a first surface 1031 of the insulation layer 103 on a side of the insulation layer 103 facing the organic light-emitting functional layer 124, as the insulating layer 103 is transparent, the light L may pass through the first surface 1031 of the insulation layer 103, then exit from a second surface 1032 of the insulation layer 103 on a side of the insulation layer 103 facing the reflective electrode 106 and reach the reflective electrode 106. The reflective electrode 106 is reflective so as to reflect the light L incident thereon back to the light emitting element 120, and the light L finally exits from the light emitting element 120. For example, the insulation layer 103 may have a high light transmittance, and the light reflected by the reflective electrode 106 exits to the outside with almost no loss, thereby ensuring a high light output brightness and a high light output efficiency of the display substrate. The insulation layers in the plurality of sub-pixels may be integrally formed to facilitate manufacturing and reduce the difficulty of the manufacturing process.

In an example, a conductive path for electrically connecting the first electrode layer and the reflective electrode may be provided in the insulation layer. For example, the insulation layer 103 may include a via hole 110 filled with a metal member 108, and the reflective electrode 106 is electrically connected to the first electrode layer 122 through the metal member 108. In this way, by forming the conductive path between the reflective electrode 106 and the first electrode layer 122 in the insulation layer 103, it is conducive to transmitting a signal provided by a pixel circuit of the display apparatus to the first electrode layer 122 through the reflective electrode 106. In this way, it is conducive to achieving the control of the pixel circuit over the light-emitting element, as well as a compact structure of the display substrate, which is beneficial to the miniaturization of device. Further, for example, the metal member 108 is made of a metal material, such as tungsten metal, and the via hole filled with tungsten metal is also referred to as a tungsten via (W-via). For example, when a thickness of the insulation layer 103 is large, forming a tungsten via in the insulation layer 103 may ensure the stability of the conductive path. In addition, as a manufacturing process of the tungsten via is mature, a surface flatness of the obtained insulation layer 103 is good, which is beneficial to reducing a contact resistance between the reflective electrode 106 and the first electrode layer 122. It may be understood that the tungsten via is not only suitable for the electrical connection between the reflective electrode 106 and the first electrode layer 122, but also suitable for an electrical connection between the reflective electrode 106 and the pixel driving circuit, and electrical connections between other wiring layers.

In an example, in some embodiments of the present disclosure, with continued reference to FIG. 3, the display substrate may further include at least one wiring layer M1 arranged between the reflective electrode 106 and the silicon-based base substrate 200. For example, the wiring layer M1 includes a metal layer, the pixel driving circuit of the light-emitting element includes a first transistor T1, the first transistor T1 includes a semiconductor layer ACT1, a gate G1, a source S1, and a drain D1. The gate G1 of the first transistor T1 is electrically connected to a gate electrode connection portion 102g through a via hole, the source S1 of the first transistor T1 is electrically connected to a source electrode connection portion 102s through a via hole, and the drain D1 of the first transistor T1 is electrically connected to a drain electrode connection portion 102d through a via hole. The gate electrode connection portion 102g, the source electrode connection portion 102s and the drain electrode connection portion 102d may be arranged in the same metal layer. For example, the gate electrode connection portion 102g, the source electrode connection portion 102s and the drain electrode connection portion 102d may be arranged in a metal layer included in the wiring layer M1.

In an example, with continued reference to FIG. 3, the reflective electrode 106 may include a metal layer 105, and a material of the metal layer 105 may be aluminum or an aluminum alloy, such as an aluminum-copper alloy. As aluminum or aluminum-copper alloy has a low resistance and a high reflectivity, the light output brightness and the light output efficiency of the display substrate may be improved. For example, a thickness of the metal layer 105 is between 10 nm and 1000 nm. If the thickness is too small, a reflection effect is not good, and if the thickness is too large, an overall thickness of the display substrate is large. The reflective electrode 106 may be used as a wiring layer M2 of the display substrate.

In an example, the display substrate may further include more metal layers. For example, the display substrate may include a metal layer used as an electrode plate of a capacitor in the pixel driving circuit or a plurality of wiring metal layers in different film layers of a driving circuit of the display substrate, so as to facilitate a wiring design. For example, the number of metal layers in the display substrate may be 5, 6, 7 or 8. When the display substrate includes a plurality of metal layers, the wiring layer M2 in which the reflective electrode 106 is located is the uppermost wiring layer, so that it is possible to simplify the manufacturing of the reflective electrode 106 without changing an underlying architecture of the display substrate.

In an example, in some embodiments of the present disclosure, with continued reference to FIG. 3, the reflective electrode 106 may further include at least one protective layer 104 stacked with the metal layer 105 and arranged on a surface of the metal layer 105 on a side of the metal layer 105 facing the silicon-based base substrate 200. In this way, the protective layer 104 may prevent the metal layer 105 from being oxidized. For example, a material of the protective layer is a conductive material, such as titanium nitride (TiN). As a surface of the metal layer 105 on a side of the metal layer 105 facing the first electrode layer 122 is not provided with the protective layer 104, the light emitted by the organic light-emitting functional layer 124 and passing through the first electrode layer 122 and the insulation layer 103 may be directly incident onto the surface of the metal layer 105, thereby reducing the loss of light at the interface and improving the light reflection efficiency and the light output brightness of the display substrate.

It should be noted that the arrangement and the number of the protective layers 104 are not limited to that shown in FIG. 3. For example, the reflective electrode may not be provided with the protective layer and may include only the metal layer. Alternatively, two protective layers may be provided in the reflective electrode, which may be arranged on opposite sides of the metal layer.

It may be understood that the protective layer described above may also be applied to other metal layers. For example, referring to FIG. 3, a protective layer may be provided on each of upper and lower sides of each metal electrode in the gate electrode connection portion 102g, the source electrode connection portion 102s and the drain electrode connection portion 102d, so as to effectively prevent these electrode connection portions from being oxidized and improve the conductivity. It may understandable that other metal layers may be provided with no protective layer, or may be provided with a protective layer on only one side thereof.

In an example, in some embodiments of the present disclosure, referring to FIG. 2, the display substrate may further include an electronic device in the edge area of the silicon-based base substrate. For example, in some exemplary embodiments, the electronic device may be a one-time programmable device OTP. The one-time programmable electronic device is used to compensate for the pixel driving circuit for the light-emitting element, so as to improve the brightness uniformity of the plurality of light-emitting elements in the display substrate and enhance the display effect of the display substrate.

FIG. 4 shows a partial enlarged schematic cross-sectional view of the display substrate taken along line BB′ shown in FIG. 2 according to some exemplary embodiments of the present disclosure, in which a correspondence between film layers of a first transistor arranged in the active area AA and film layers of a second transistor arranged in the edge area EA is shown;

In an example, in some embodiments of the present disclosure, referring to FIG. 4, the electronic device OTP is arranged in the edge area EA. The electronic device OTP includes a second transistor T2, and the second transistor T2 includes a semiconductor layer ACT2, a gate G2, a source S2, and a drain D2. The pixel driving circuit for the light-emitting element is arranged in the active area AA, and the pixel driving circuit includes a first transistor T1 and a plurality of conductive wires or conductive portions. The first transistor T1 includes a semiconductor layer ACT1, a gate G1, a source S1, and a drain D1. The semiconductor layer ACT2, the gate G2, the source S2 and the drain D2 of the second transistor T2 are respectively located in the same layers as the semiconductor layer ACT1, the gate G1, the source S1 and the drain D1 of the first transistor T1. That is, the semiconductor layer ACT1 and the semiconductor layer ACT2 are in the same layer, the gate G1 and the gate G2 are in the same layer, the source S1 and the source S2 are in the same layer, and the drain D1 and the drain D2 are in the same layer. The transistor of the electronic device OTP and the transistor of the pixel driving circuit may be manufactured in the same layers, which may save on process steps and simplify the manufacturing process.

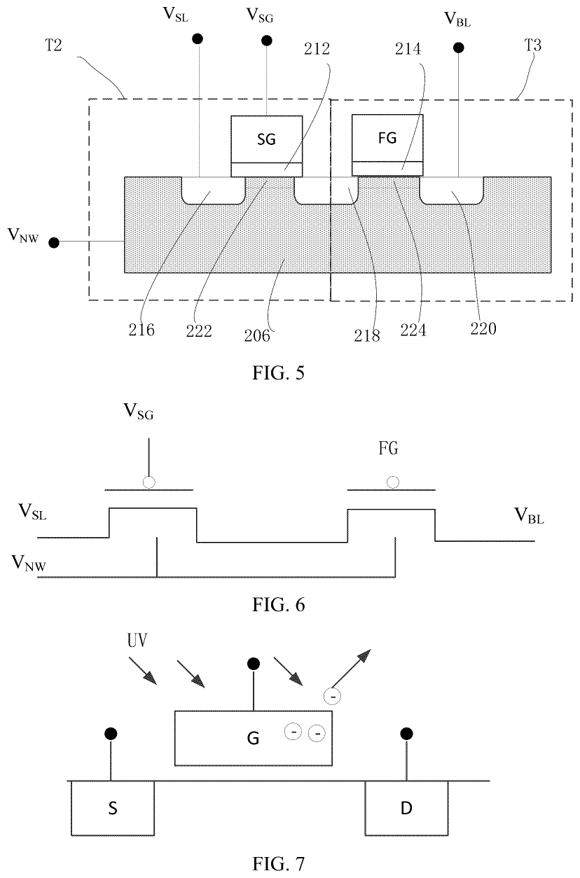

FIG. 5 shows a schematic cross-sectional view of a single electronic device OTP in the display substrate taken along line DD′ shown in FIG. 2 according to some embodiments of the present disclosure. FIG. 6 shows an equivalent circuit diagram of the electronic device OTP shown in FIG. 5.

For example, in some embodiments of the present disclosure, the one-time programmable electronic device OTP in the display substrate may include a pair of transistors connected in series. For example, the OTP may include a second transistor T2 and a third transistor T3, and the second transistor T2 and the third transistor T3 are connected in series. For example, the second transistor T2 may be a selection transistor having a selection gate, and the third transistor T3 may be a storage transistor having a floating gate; alternatively, the second transistor T2 may be a storage transistor having a floating gate, and the third transistor T3 may be a selection transistor having a selection gate. The floating gate of the storage transistor is used to store data bits, and values of the data bits depend on an amount of charges stored by the floating gate. The selection gate of the selection transistor is used to prevent charges from leaking out of the floating gate. The semiconductor layer, the gate, the source and the drain of the second transistor T2 are respectively arranged in the same layers as the semiconductor layer, the gate, the source and the drain of the first transistor T3. That is, the second transistor and the third transistor may be manufactured in the same layers, which saves on process steps. The second transistor T2 may be a P-type doped transistor or an N-type doped transistor; and/or the third transistor T3 may be a P-type doped transistor or an N-type doped transistor.

In an example, in some embodiments of the present disclosure, referring to FIG. 5, the second transistor T2 is a selection transistor, and the third transistor T3 is a storage transistor. The selection transistor and the storage transistor are arranged on one or more corresponding main body regions 206 and are connected in series. The gate SG of the selection transistor and the gate FG of the storage transistor are laterally spaced apart from each other, and are respectively isolated from the main body region 206 through insulation layers 212 and 214. The selection gate SG of the selection transistor is electrically connected to a first terminal V_{SG} of the electronic device OTP, and the floating gate FG of the storage transistor is used to store data bits. The bit is determined to be logic “1” or logic “0” based on an amount of charges stored on the floating gate FG.

The source/drain regions 216, 218 and 220 of the select transistor and the storage transistor are arranged in the main body region 206 and are located on opposite sides of the select gate SG and opposite sides of the floating gate FG. In addition, the source/drain regions 216, 218, and 220 define a channel region 222 of the selection transistor and a channel region 224 of the storage transistor. The channel region 222 is arranged under the selection gate SG of the selection transistor, and channel region 224 is arranged under the floating gate FG of the storage transistor. The semiconductor layers of the selection transistor and the storage transistor are respectively located in their respective channel regions. In some embodiments, the source/drain region 216 of the selection transistor is electrically connected to a second terminal V_{SL} of the electronic device OTP, the source/drain region 220 of the storage transistor is electrically connected to a third terminal V_{BL} of the electronic device OTP, and the main body region 206 is electrically connected to a fourth terminal V_{NW} of the electronic device OTP.

In an example, referring to FIG. 6, under a programming state, if an OTP memory cell is going to be programmed, the memory cell to be programed is selected using the first terminal V_{SG} and the third terminal V_{BL}, then the selection transistor is turned on (with the first terminal V_{SG} corresponding thereto receiving a high negative potential (such as −5V), and the fourth terminal V_{NW} and the second terminal V_{SL} corresponding thereto being grounded), and then the third terminal V_{BL} receives a high negative potential (such as −5V). In this way, a strong sourcing current may be generated in the channel, and due to a hot carrier effect, some of the electrons will move to the floating gate FG (state 1). If it is not under the programming state, there are no electrons on the floating gate FG (state 0). In a normal reading state, the first terminal V_{SG} and the third terminal V_{BL} only receive a low potential, such as −1.8V. If there are charges on the floating gate FG, the memory cell may have a large current. If there is no charge on the floating gate FG, the current of the entire OTP memory cell is small. This method is used to determine whether the memory cell of an OTP memory is in the state 1 or the state 0.

As described above, after being programmed, there are charges on the floating gate FG, which is defined as the state 1. However, in the manufacturing process of the silicon-based OLED display substrate, charges on the floating gate FG of the one-time programmable electronic device OTP may be affected by other processes in the manufacturing process, resulting in charge loss. The charge loss may cause the logic state of the one-time programmable electronic device OTP to change, and may further lead to a failure of compensation for the corresponding pixel driving circuit, thereby causing a failure of the silicon-based OLED display product.

FIG. 7 shows a schematic diagram of charge loss on a floating gate FG in an OTP of a display substrate according to some embodiments of the present disclosure.

In an example, referring to FIG. 7, in the manufacturing process of the silicon-based OLED, the UV used for curing a CG bonding adhesive and an FPC bonding reinforcement adhesive during encapsulation is partially irradiated on the OTP for the silicon-based OLED, which may cause charges on the floating gate FG in the OTP to escape from it, thereby causing the programming state of the OTP to change, thereby further causing a failure of compensation by the OTP. This may cause abnormal display or a black screen of the silicon-based OLED display product, seriously affecting the display product yield. In addition to the irradiation of a UV radiation energy in a UV curing process, which may cause charges on the floating gate FG in the OTP to escape from it, in an ion sputtering coating process, some energy is radiated on the OTP for the silicon-based OLED, which may also cause the charges on the floating gate FG in the OTP to escape from it.

In order to reduce or eliminate the impact of the energy radiation in the ion sputtering coating process on the OTP or the energy radiation in the UV curing process on the OTP, a metal shielding portion may be arranged above the OTP. The metal shielding portion may shield the energy radiation in the ion sputtering coating process or the energy radiation in the UV curing process, so as to shield and protect the OTP, thereby ensuring the stability of the state of the OTP.

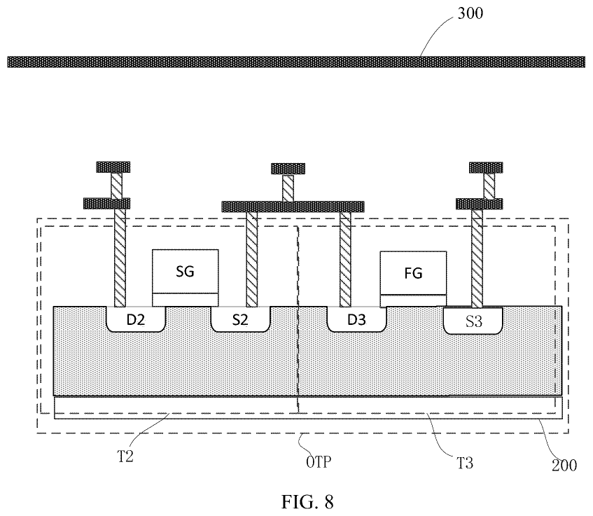

FIG. 8 shows a partial schematic cross-sectional view of an OTP area of the display substrate taken along line DD′ shown in FIG. 2 according to some other embodiments of the present disclosure, in which a metal shielding portion is shown.

In an example, in some embodiments of the present disclosure, referring to FIG. 8, the electronic device OTP includes a memory cell, which includes a pair of transistors. For example, the pair of transistors includes a second transistor T2 and a third transistor T3, and the pair of transistors are arranged on the silicon-based base substrate and electrically connected in series. Conductive components are arranged and stacked above the pair of transistors and arranged in layers in which interconnection structures of the OTP memory cell are located. An orthographic projection of the metal shielding portion 300 on the silicon-based base substrate 200 covers orthographic projections of the pair of transistors on the silicon-based base substrate 200.

In order to prevent the charges on the floating gate FG in the OTP from escaping, the metal shielding portion 300 is arranged above a region where the OTP is located. The metal shielding portion 300 is arranged in the edge area of the silicon-based base substrate, and the metal shielding portion is located on a side of each of layers in which the semiconductor layer, the gate, the source and the drain of the transistor in the OTP are respectively located away from the silicon-based base substrate 200. For example, the metal shielding portion 300 is arranged on a side of each of layers in which the semiconductor layer, the gate, the source and the drain of the second transistor T2 are respectively located away from the silicon-based base substrate 200.

Different designs of the shape, the thickness and the position of the metal shielding layer will affect the shielding effect, resulting in different protection effects on the OTP of electronic devices.

For example, in some embodiments of the present disclosure, referring to FIG. 8, in order to improve the protection effect of the metal shielding portion on the electronic device OTP, the orthographic projection of the metal shielding portion 300 on the silicon-based base substrate may cover the orthographic projection of the electronic device OTP on the silicon-based base substrate. By causing the orthographic projection of the metal shielding portion on the silicon-based base substrate to cover the orthographic projection of the electronic device OTP on the silicon-based base substrate, a range of shielding protection of the metal shielding portion to the OTP may be increased, and part of the radiation energy in the ion sputtering coating process or part of the radiation energy in the UV curing process may be well shielded. In this way, the electronic device OTP may be provided with a good protection, a probability of charge escape in the electronic device OTP may be reduced, and a stability of the programmable state of the OTP may be increased, thereby improving the display effect of the silicon-based OLED display substrate.

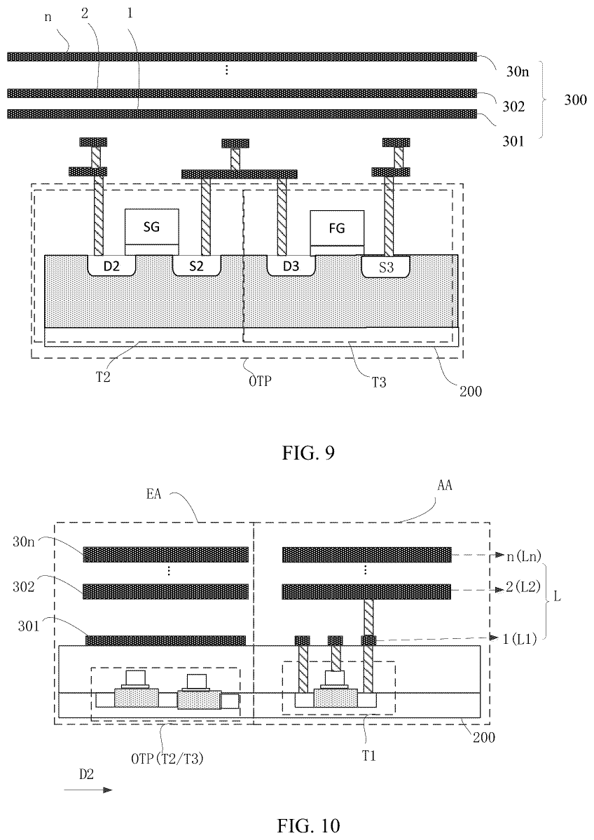

FIG. 9 shows a partial schematic cross-sectional view of an OTP area of a display substrate according to some other embodiments of the present disclosure.

In an example, in some embodiments of the present disclosure, referring to FIG. 9, the display substrate further includes n metal film layers, such as a metal film layer 1, a metal film layer 2 . . . and a metal film layer n. The n metal film layers are located on a side of a layer in which the source and the drain of the electronic device OTP are located away from the silicon-based base substrate 200, the plurality of metal film layers are sequentially arranged away from the silicon-based base substrate, and n is a positive integer greater than or equal to 2, for example, n may be 5, 6, 7 or 8.

The metal shielding portion 300 includes n metal shielding sub-portions, and the n metal shielding sub-portions are arranged in the n metal film layers, respectively. For example, with continued reference to FIG. 9, the metal shielding portion 300 includes a metal shielding sub-portion 301, a metal shielding sub-portion 302 . . . and a metal shielding sub-portion 30n. The metal shielding sub-portion 301 is arranged in the metal film layer 1, the metal shielding sub-portion 302 is arranged in the metal film layer 2, and the metal shielding sub-portion 30n is arranged in the metal film layer n. By arranging the plurality of metal shielding sub-portions in different layers, a total thickness of the metal shielding portion may be increased, thereby providing a better shielding effect for the energy radiation in the sputtering coating process or the radiation in UV curing process. In this way, the OTP may be provided with a better protection, thus the yield of silicon-based OLED display products may be improved.

FIG. 10 shows a partial schematic cross-sectional view of the display substrate taken along line BB′ shown in FIG. 2 according to some embodiments of the present disclosure, in which a correspondence between film layers of metal film layers in an active area and film layers of a metal shielding portion in an edge area is shown.

In an example, in some embodiments of the present disclosure, referring to FIG. 10, the display substrate further includes n conductive connection portions L arranged in the active area AA. For example, the conductive connection portions may be conductive components such as wires and connection portions in the pixel driving circuit. The n conductive connection portions L are respectively arranged in the n metal film layers. For example, the n conductive connection portions include a conductive connection portion L1, a conductive connection portion L2 . . . and a conductive connection portion Ln. The conductive connection portion L1 is arranged in the metal film layer 1, the conductive connection portion L2 is arranged in the metal film layer 2, and the conductive connection portion Ln is arranged in the metal film layer n. Each of the n metal shielding sub-portions and a respective one of the n conductive connection portions may be arranged in the same metal film layer. For example, the metal shielding sub-portion 301 and the conductive connection portion L1 may be arranged in the metal film layer 1, the metal shielding sub-portion 302 and the conductive connection portion L2 may be arranged in the metal film layer 2, and the metal shielding sub-portion 30n and the conductive connection portion Ln may be arranged in the metal film layer n. For the n metal shielding sub-portions and the n conductive connection portions, the metal shielding sub-portion and the conductive connection portion arranged in the same metal film layer have the same thickness. That is, the metal shielding portion may be manufactured in the same process as the metal film layer in the active area, without using an additional mask, thus saving on the manufacturing cost.

In an example, in some embodiments of the present disclosure, with continued reference to FIG. 10, orthographic projections of the n metal shielding portions on the silicon-based base substrate at least partially overlaps with an orthographic projection of the same electronic device on the silicon-based base substrate. For example, the metal shielding sub-portion 301 at least partially overlaps with the orthographic projection of an electronic device OTP on the silicon-based base substrate, the metal shielding sub-portion 302 also at least partially overlaps with the orthographic projection of the same electronic device OTP on the silicon-based base substrate, and the metal shielding sub-portion 30n also at least partially overlaps with the orthographic projection of the same electronic device OTP on the silicon-based base substrate. Orthographic projections of any two of the n metal shielding sub-portions arranged in the n metal layers on the silicon-based base substrate may overlap with each other, for example, orthographic projections of the metal shielding sub-portion 301 and the metal shielding sub-portion 302 on the silicon-based base substrate overlap with each other, orthographic projections of the metal shielding sub-portion 301 and the metal shielding sub-portion 30n on the silicon-based base substrate overlap with each other, and orthographic projections of the metal shielding sub-portion 302 and the metal shielding sub-portion 30n on the silicon-based base substrate overlap with each other. That is, shapes of the orthographic projections of the n metal shielding sub-portions arranged in different metal film layers on the silicon-based base substrate may be identical to each other, so are positions of the orthographic projections of the n metal shielding sub-portions on the silicon-based base substrate. By stacking a plurality of layers of metal shielding sub-portions, a total thickness of the metal shielding portion may be increased, thereby permitting a better shielding effect on the energy radiation in the sputtering coating process or the energy radiation in the UV curing process. Therefore, the OTP may be further protected, thereby improving the yield of silicon-based OLED display products.

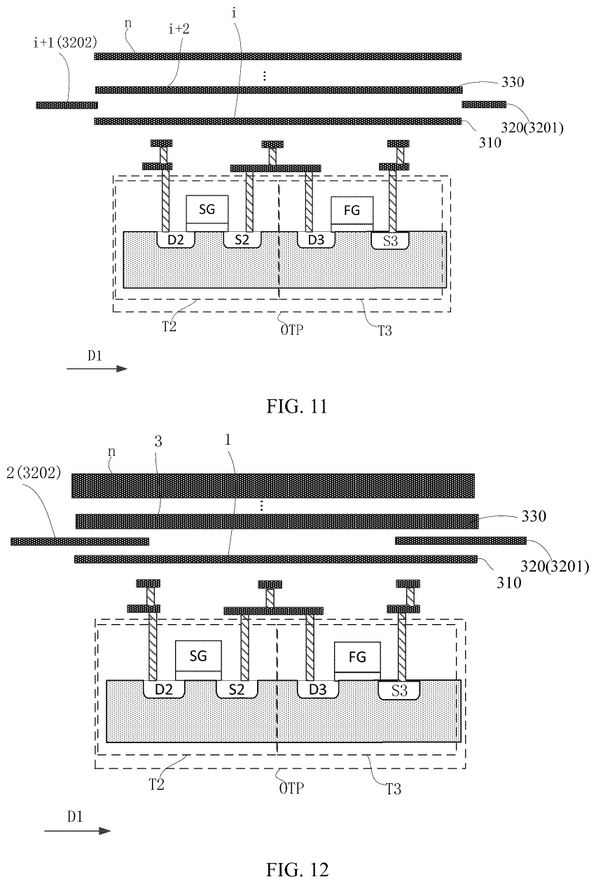

FIG. 11 shows a partial schematic cross-sectional view of an OTP area of the display substrate taken along line DD′ shown in FIG. 2 according to some other embodiments of the present disclosure.

For example, in some embodiments of the present disclosure, the n metal shielding portions include: a plurality of first metal shielding sub-portions 310 arranged in an i^{th} metal film layer; and a plurality of second metal shielding sub-portions 320 arranged in an (i+1)^{th} metal film layer, where i is a positive integer greater than or equal to 1 and less than or equal to (n−2). For example, when i is equal to 1, referring to FIG. 11, the first metal shielding sub-portion 310 may be arranged in the metal film layer 1, and the second metal shielding sub-portion 320 may be arranged in the metal film layer 2. Orthographic projections of the plurality of first metal shielding sub-portions 310 on the silicon-based base substrate and orthographic projections of the plurality of second metal shielding sub-portions 320 on the silicon-based base substrate are alternately arranged in the first direction D1. The metal shielding portion may include a plurality of metal shielding sub-portions arranged in the same metal film layer. For example, the second metal shielding sub-portion 320 in the metal film layer 2 may include a plurality of metal shielding sub-portions. For example, the second metal shielding sub-portion 320 may include a metal shielding sub-portion 3201 and a metal shielding sub-portion 3202. Any two adjacent metal shielding sub-portions in the same metal film layer are arranged at intervals. For example, the metal shielding sub-portion 3201 and the metal shielding sub-portion 3202 of the second metal shielding sub-portion 320 are arranged at intervals. By implementing the metal shielding sub-portions arranged in a plurality of metal film layers as segments, it is possible to avoid forming an excessively large area caused by densely arranging the metal shielding portions, thereby preventing a large number of charged ions from gathering which causes a risk of electrostatic damage to OTP.

In an example, with continued reference to FIG. 11, the n metal shielding sub-portions further include: a plurality of third metal shielding sub-portions 330 arranged in an (i+2)^{th} metal film layer; and orthographic projections of the plurality of third metal shielding sub-portions 330 on the silicon-based base substrate and the orthographic projections of the plurality of second metal shielding sub-portions 320 on the silicon-based base substrate are alternately arranged in the first direction D1. By arranging the metal shielding sub-portions in adjacent layers in a staggered manner, it is possible to avoid forming an excessively large area caused by densely arranging the metal shielding portions, thereby preventing a large number of charged ions from gathering which causes the risk of electrostatic damage to OTP.

In an example, in some embodiments, with continued reference to FIG. 11, each of the orthographic projections of the plurality of first metal shielding sub-portions 310 on the silicon-based base substrate coincides with a respective one of the orthographic projections of the plurality of third metal shielding sub-portions 330 on the silicon-based base substrate. By stacking thicknesses of the plurality of metal shielding sub-portions in different metal film layers, it is possible to prevent the radiation energy from penetrating the shielding layer and damaging the OTP, thereby improving a shielding capability of the metal shielding portion and further improving the display effect of the display substrate.

In an example, in some embodiments of the present disclosure, orthographic projections of at least two of the n metal shielding sub-portions arranged in the n metal film layers on the silicon-based base substrate may at least not partially overlap with each other. For example, with continued reference to FIG. 11, the orthographic projection of the first metal shielding sub-portion 310 arranged in the metal film layer 1 on the silicon-based base substrate and an orthographic projection of the metal shielding sub-portion 3201 arranged in the metal film layer 2 on the silicon-based base substrate may at least not partially overlap with each other.

In an example, the n metal shielding sub-portions may have a same thickness.

By arranging the metal shielding sub-portions in adjacent layers in a staggered manner, it is possible to avoid forming an excessively large area caused by densely arranging the metal shielding portions, thereby preventing a large number of charged ions from gathering which causes the risk of electrostatic damage to OTP. The arrangement of the metal shielding sub-portions in adjacent layers may be various. For example, the metal shielding sub-portions may be designed to be arranged in a different staggered manner, in which oblique radiation may be blocked, thereby improving the shielding effect of the metal shielding portions. It should be noted that embodiments of the present disclosure do not limit an area of an overlap between a metal shielding sub-portion over the OTP and a metal shielding sub-portion over a region adjacent to the OTP.

FIG. 12 shows a partial schematic cross-sectional view of an OTP area of the display substrate taken along line DD′ shown in FIG. 2 according to some other embodiments of the present disclosure.

In an example, in some embodiments of the present disclosure, referring to FIG. 12, the n metal shielding sub-portions in the metal shielding portion include a first metal shielding sub-portion 310, a second metal shielding sub-portion 320, and a third metal shielding sub-portion 330. An orthographic projection of at least one second metal shielding sub-portion 320 on the silicon-based base substrate partially overlaps with an orthographic projection of an adjacent first metal shielding sub-portion 310 on the silicon-based base substrate or an orthographic projection of an adjacent third metal shielding sub-portion 330 on the silicon-based base substrate.

By optimizing the staggered arrangement of the metal shielding sub-portions in the plurality of metal film layers, it is possible for the orthographic projection of the metal shielding portion on the silicon-based base substrate to completely cover the entire OTP area, without leaving any gaps. In other words, there is no hollow area arranged within a range of the orthographic projection of the metal shielding portion on the silicon-based base substrate. Therefore, the existence of an area without energy radiation shielding may be avoided, thus the shielding effect of the metal shielding portion may be improved, which is beneficial to the stability of the OTP and the improvement of the display effect of the display substrate.

In an example, with continued reference to FIG. 12, at least two of the n metal shielding sub-portions may have different thicknesses. For example, a thickness of the first metal shielding sub-portion 310 may be different from a thickness of the third metal shielding sub-portion 330. That is, the n metal shielding sub-portions arranged in different metal film layers may have thicknesses different from each another, which is conducive to manufacturing the n metal shielding sub-portions in the same layers as the metal layers in the active area, without separate processes, so that the cost may be reduced.

In an example, in some embodiments of the present disclosure, referring to FIG. 2, the display substrate may include m electronic devices OTP and m metal shielding portions 300, where m is a positive integer greater than or equal to 2.

Each of orthographic projections of the m metal shielding portions 300 on the silicon-based base substrate covers a respective one of orthographic projections of the m electronic devices OTP on the silicon-based base substrate. Orthographic projections of at least two metal shielding portions adjacent to each other among the m metal shielding portions on the silicon-based base substrate are arranged at intervals in the first direction.

By providing a metal shielding portion for each of the electronic devices in the display substrate, all of the electronic devices may be shielded and protected. Therefore, damage to the OTP caused by the impact of radiation on the electronic devices OTP may be prevented, thus defects such as abnormal display of the display substrate or a black screen of the display substrate may be prevented.

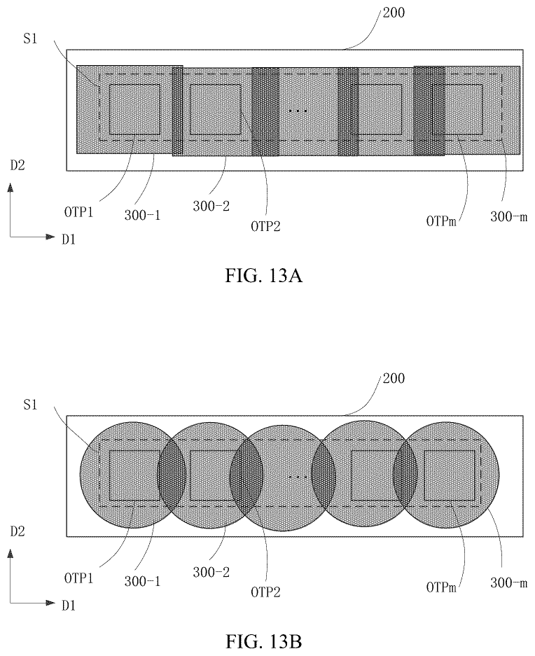

FIG. 13A and FIG. 13B show schematic plan views of an OTP area of a display substrate according to some embodiments of the present disclosure.

In an example, in some embodiments of the present disclosure, orthographic projections of any two metal shielding portions adjacent to each other among the m metal shielding portions on the silicon-based base substrate at least partially overlap with each other, such that the orthographic projections of the m metal shielding portions on the silicon-based base substrate 200 extend continuously in the first direction D1. For example, referring to FIG. 13A, an orthographic projection of a metal shielding portion 300-1 and an orthographic projection of a metal shielding portion 300-2 adjacent to the metal shielding portion 300-1 on the silicon-based base substrate 200 partially overlap with each other. By optimizing the staggered arrangement of the metal shielding sub-portions in the plurality of metal film layers, it is possible for the orthographic projection of the metal shielding portion on the silicon-based base substrate to completely cover an entire area S1 in which the OTP is located, without leaving any gaps. In other words, there is no hollow area arranged within a range of the orthographic projection area of the metal shielding portion on the silicon-based base substrate. Therefore, the existence of an area without energy radiation shielding may be avoided, thus the shielding effect of the metal shielding portion may be improved, which is beneficial to the stability of the OTP and the improvement of the display effect of the display substrate.

It should be noted that an outline of the metal shielding portion shown in some embodiments of the present disclosure is in a shape of a rectangle, however the shape of the outline of the metal shielding portion in the present disclosure is not limited thereto. For example, referring to FIG. 13B, the outline of the metal shielding portion may also be in a shape of a circle. Likewise, the metal shielding portion may also be in a shape of an ellipse, a polygon, or other shapes. The present disclosure does not limit the shape of the metal shielding portion.

Orthographic projections of any two metal shielding portions adjacent to each other among metal shielding portions of different shapes on the silicon-based base substrate at least partially overlap with each other, such that the orthographic projections of the m metal shielding portions on the silicon-based base substrate extend continuously in the first direction. In this way, the shielding effect of the metal shielding portion may be improved, which is beneficial to the stability of the OTP and the improvement of the display effect of the display substrate.

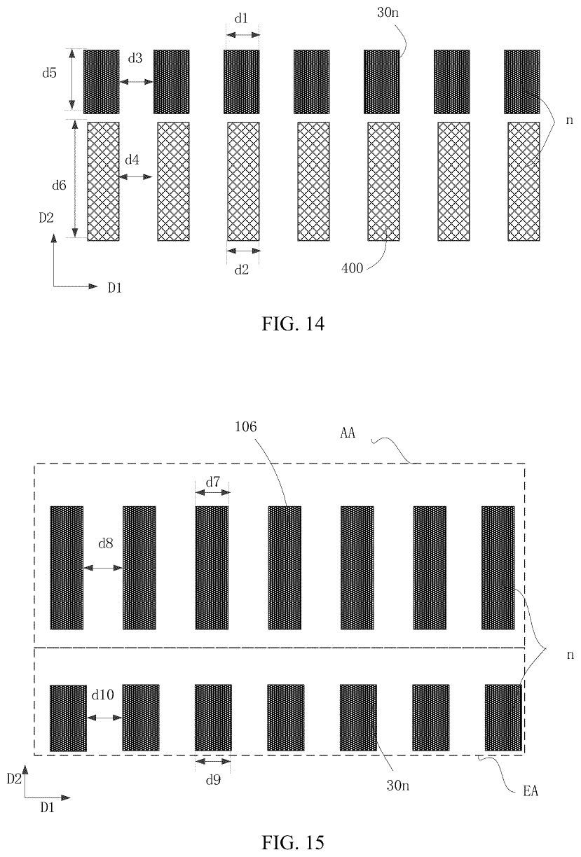

FIG. 14 shows a schematic plan view of metal shielding portions and bonding terminals of a display substrate according to some other embodiments of the present disclosure.

In an example, in some embodiments of the present disclosure, the metal shielding portion 300 include a plurality of metal shielding sub-portions arranged in the same metal film layer as the plurality of bonding terminals 400, referring to FIG. 14. For example, the plurality of bonding terminals 400 and the plurality of metal shielding sub-portions may be arranged in a top metal film layer n, and the plurality of metal shielding sub-portions may be referred to as 30n. A dimension d1 of each of the plurality of metal shielding sub-portions 30n arranged in the same metal film layer as the plurality of bonding terminals 400 in the first direction D1 is substantially equal to a dimension d2 of a respective one of the plurality of bonding terminals 400 in the first direction. And/or, a dimension d3 of a gap between any two of the plurality of metal shielding sub-portions 30n arranged in the same metal film layer as the plurality of bonding terminals 400 in the first direction is substantially equal to a dimension d4 of a gap between any two of the plurality of bonding terminals in the first direction. Herein, the expression “substantially equal to” means that a ratio of dimensions of the two is in a range of 0.8 to 1.2, for example, d1/d2 is in the range of 0.8 to 1.2. Dimensions of the plurality of terminals may be the same or different; and/or gaps between terminals adjacent to each other may be the same or different.

A dimension d5 of each of the plurality of metal shielding sub-portions 30n arranged in the same metal film layer as the plurality of bonding terminals 400 in the second direction is less than a dimension d6 of a respective one of the plurality of bonding terminals 400 in the second direction. That is, d5 is less than d6.

By configuring the metal shielding sub-portion arranged in the same metal film layer as the bonding terminal to have a dimension in the first direction substantially equal to that of the corresponding bonding terminal in the first direction, and a dimension in the second direction less than that of the corresponding bonding terminal in the second direction, it is possible to balance an etch loading effect of the metal shielding sub-portion arranged in the same metal film layer as the bonding terminal and an etch loading effect of the bonding terminal, so as to improve the etching uniformity.

FIG. 15 shows a schematic plan view of a top-layer metal shielding sub-portion and a reflective electrode of a display substrate according to some other embodiments of the present disclosure.

In an example, in some embodiments of the present disclosure, with reference to FIG. 3, FIG. 10 and FIG. 15, at least one sub-pixel further includes a reflective electrode 106, and a film layer in which the reflective electrode 106 is located is arranged between a film layer in which the pixel driving circuit is located and a film layer in which the light-emitting element 120 is located. The metal shielding portion 300 further includes a plurality of top-layer metal shielding sub-portions 30n arranged in the same layer as the reflective electrode 106. A dimension d9 of each of the plurality of top-layer metal shielding sub-portions 30n in the first direction D1 is substantially equal to a dimension d7 of a respective one of a plurality of reflective electrodes 106 in the first direction; and/or a dimension d10 of a gap between any two of the plurality of top-layer metal shielding sub-portions 30n in the first direction is substantially equal to a dimension d8 of a gap between any two of a plurality of reflective electrodes in the first direction. Here, the expression “substantially equal to” means that a ratio of dimensions of the two is in a range of 0.8 to 1.2, for example, d7/d9 is in the range of 0.8 to 1.2.

By means of such design, it is possible to balance an etch loading effect of the reflective electrode and an etch loading effect of the top-layer metal shielding sub-portion, thereby improving the etching uniformity.

In an example, in some embodiments of the present disclosure, the bonding terminal 400 may be arranged in the top-layer metal layer n. With reference to FIG. 14 and FIG. 15, the dimension d2 of each of the plurality of bonding terminals in the first direction may be substantially equal to the dimension d7 of each of the plurality of reflective electrodes 106 in the first direction. By means of such design, it is possible to balance the etch loading effect of the reflective electrode and an etch loading effect of the bonding terminal, thereby improving the etching uniformity.

It should be noted that a dimension of a metal shielding sub-portion arranged in other film layer in the first direction may also be substantially equal to that of a metal wire arranged in the same layer in the AA area in the first direction; and/or, a distance between metal shielding sub-portions arranged in other film layer may also be substantially equal to a distance between metal wires arranged in the same layer in the AA area in the first direction. By means of such design, it is possible to balance the etch loading effect of the metal shielding sub-portion and the etch loading effect of the metal wire arranged in the same film layer in the AA area, thereby improving etching uniformity.

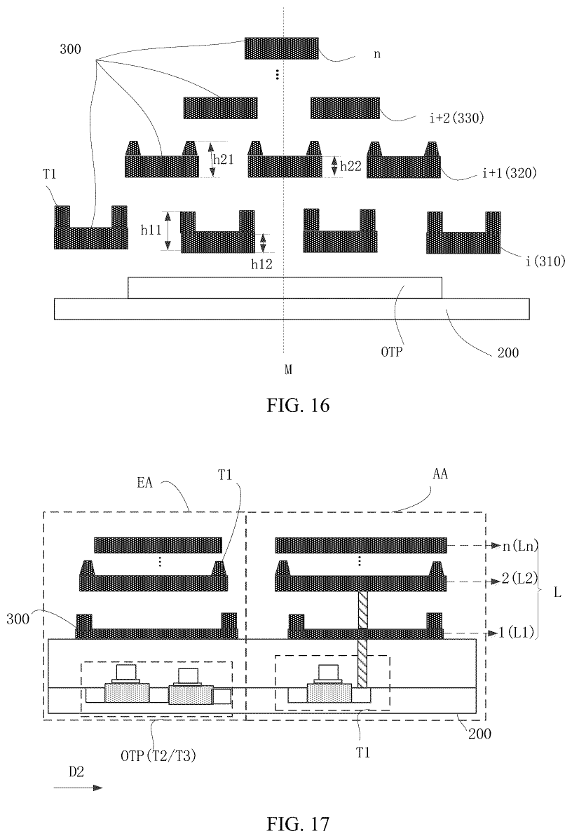

FIG. 16 shows a schematic structural diagram of a metal shielding layer corresponding to a single OTP according to some embodiments of the present disclosure.

In an example, in some embodiments of the present disclosure, referring to FIG. 16, the display substrate includes n metal film layers, and n is greater than or equal to 3. The n metal film layers include an i^{th} metal film layer, an (i+1)^{th} metal film layer and an (i+2)^{th} metal film layer, and i is greater than or equal to 1 and less than or equal to (n−2). The (i+1)^{th} metal film layer is arranged on a side of the i^{th} metal film layer away from the silicon-based base substrate 200, and the (i+2)^{th} metal film layer is arranged on a side of the (i+1)^{th} metal film layer away from the silicon-based base substrate 200. The display substrate further includes a metal shielding portion 300, and the metal shielding portion 300 includes: a first metal shielding sub-portion 310 arranged in the i^{th} metal film layer; a second metal shielding sub-portion 320 arranged in the (i+1)^{th} metal film layer; and a third metal shielding sub-portion 330 arranged in the (i+2)^{th} metal film layer.

An edge of the second metal shielding sub-portion 320 is indented towards a center (as shown by the dashed line M in the figure) of an electronic device OTP corresponding to the first metal shielding sub-portion 310 and the second metal shielding sub-portion 320 relative to an edge of the first metal shielding sub-portion 310, and an edge of the third metal shielding sub-portion 330 is indented towards a center of an electronic device OTP corresponding to the second metal shielding sub-portion 320 and the third metal shielding sub-portion 330 relative to an edge of the second metal shielding sub-portion 320.

Metal shielding sub-portions in the plurality of metal film layers corresponding to the same electronic device OTP are arranged in a stepped manner, so that it is possible to avoid the top-layer metal shielding sub-portion being close to a cutting path area in a cutting process of the wafer, thereby reducing the risk of ESD damage.

In an example, in some embodiments of the present disclosure, with continued reference to FIG. 16, a protrusion T1 is provided at an edge of the first metal shielding sub-portion 310, such that a thickness h11 of the first metal shielding sub-portion at the edge of the first metal shielding sub-portion is greater than a thickness h12 of the first metal shielding sub-portion at a center of the first metal shielding sub-portion; and/or a protrusion is provided at an edge of the second metal shielding sub-portion 320, such that a thickness h21 of the second metal shielding sub-portion at the edge of the second metal shielding sub-portion is greater than a thickness h22 of the second metal shielding sub-portion at a center of the second metal shielding sub-portion.

Protrusions are arranged on an edge of the bottom metal, or edges of the bottom metal and a plurality of layers of metal on the bottom metal, the protrusions may block oblique radiation, which is conducive to further blocking the radiation energy. In this way, the shielding effect of the metal shielding layer may be improved, which is conducive to protecting the stability of the OTP programmable state, thereby improving the display effect of silicon-based OLED display product.

FIG. 17 shows a partial schematic cross-sectional view of the display substrate taken along line BB′ shown in FIG. 2 according to some exemplary embodiments of the present disclosure, in which a metal shielding sub-portion and a conductive connection portion arranged in a same layer are shown.

In an example, in some embodiments of the present disclosure, the metal shielding portion includes a plurality of metal shielding sub-portions. An edge of at least one metal shielding sub-portion is provided with a protrusion T1. Referring to FIG. 17, a shape of a cross-section of the protrusion T1 of the at least one metal shielding sub-portion perpendicular to an upper surface of the silicon-based base substrate 200 is the same as a shape of a cross-section of a conductive connection portion L arranged in a same layer as the at least one metal shielding sub-portion perpendicular to the upper surface of the silicon-based base substrate. For example, the cross-section of the protrusion at the edge may be in a shape of a rectangle or a trapezoid, and cross-sections of protrusions at edges in different layers may be in different shapes. By means of such design, it may be ensured that the metal shielding portion 300 in the edge area EA is manufactured in the same layers as the metal layers in the AA area, without the need to specifically adjust the etching process for the area in which the metal shielding portion is located, which is conducive to simplifying the process flow and saving on the cost.

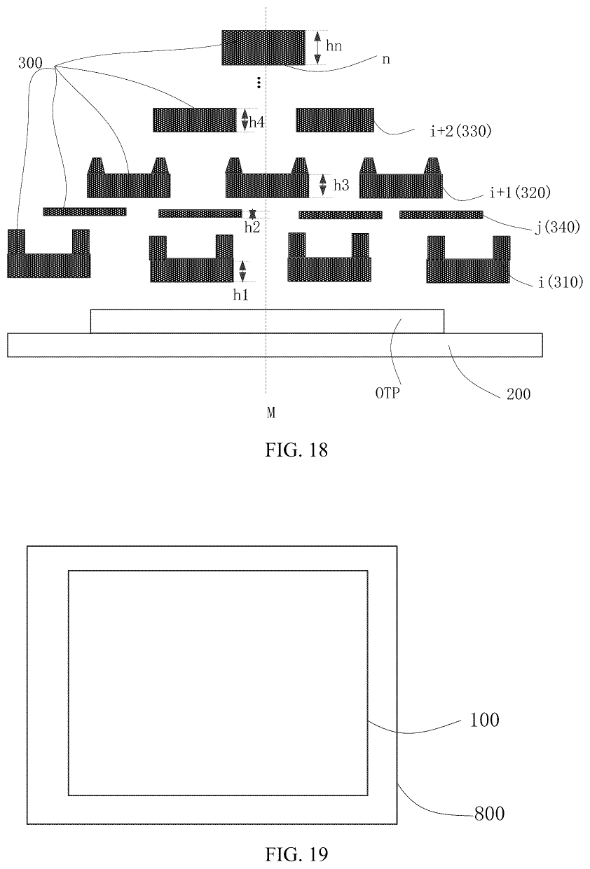

FIG. 18 shows a schematic structural diagram of a metal shielding layer corresponding to a single OTP according to some other embodiments of the present disclosure.

In an example, in some embodiments of the present disclosure, referring to FIG. 18, the n metal shielding portions further include a fourth metal shielding sub-portion 340 arranged in a j^{th} metal film layer, j is a positive integer greater than 1 and less than n. The pixel driving circuit further includes a capacitor, at least one electrode plate of the capacitor is arranged in the j^{th} metal film layer. A thickness h2 of the fourth metal shield sub-portion is less than any one of a thickness h1 of the first metal shield sub-portion, a thickness h3 of the second metal shield sub-portion and a thickness h4 of the third metal shield sub-portion.

In an example, in some embodiments of the present disclosure, the display substrate includes a metal shielding portion, and the metal shielding portion includes n metal shielding sub-portions arranged in n metal film layers. A sum of thicknesses of the n metal shielding sub-portions meets the following requirements:

$$H \geq δ ; δ = \sqrt{\frac{2}{ω μ σ}}$$

Here, δ and ω are respectively a penetration depth and a frequency of radiation rays irradiated on the metal shielding portion, μ and σ are respectively a magnetic conductivity and an electrical conductivity of the metal shielding portion, and H is the sum of the thicknesses of the n metal shielding sub-portions. For example, the thicknesses of the n metal shielding sub-portions are h1, h2 . . . and hn, respectively, thus the sum of the thicknesses of the n metal shielding sub-portions is: H=h1+h2+ . . . +hn. For example, when n is 4, H=h1+h2+h3+h4. By designing a total thickness of the n metal shielding sub-portions in the n metal film layers to exceed a penetration depth of radiation rays irradiated on the metal shielding portions, it is possible to completely shield the electronic device OTP from the energy radiation and UV irradiation, thereby improving the yield of silicon-based OLED display products.

For example, in the embodiments of the present disclosure, the metal shielding portion 300 is arranged in a fragmented manner on a side of each of layers in which the semiconductor layer, the gate, the source and the drain of the second transistor T2 are respectively located away from the silicon-based base substrate. The expression “arranged in a fragmented manner” includes various situations described in above embodiments. For example, with reference to FIG. 2 and FIG. 8, the orthographic projections of the metal shielding portion 300 on the silicon-based base substrate are discontinuously distributed, that is, the metal shielding portion 300 is discontinuously distributed in a direction parallel to the upper surface of the silicon-based base substrate. For another example, referring to FIG. 9, the metal shielding portion 300 is discontinuously distributed in a vertical direction perpendicular to the upper surface of the silicon-based base substrate. For another example, referring to FIGS. 11, 12 and 16 to 18, the metal shielding portion 300 is discontinuously distributed in each of the direction parallel to the upper surface of the silicon-based base substrate and the vertical direction perpendicular to the upper surface of the silicon-based base substrate.

In the display substrate provided in embodiments of the present disclosure, the metal shielding portion is arranged above the electronic device, so that it is possible to shield the electronic device from energy radiation and UV irradiation in the manufacturing process, so as to maintain the stability of the electronic device. Further, as the metal shielding portions are discontinuously distributed, there is no large block or large area formed by the metal shielding portions. Therefore, the impact of reflection by the metal shielding portions on the display effect may be reduced, and uniformity of the manufacturing process may be also improved.

FIG. 19 shows a schematic structural diagram of a display apparatus according to some embodiments of the present disclosure.

Optionally, embodiments of the present disclosure further provides a display apparatus. Referring to FIG. 19, the display apparatus 800 may include the display substrate 100 described above. The display apparatus may include, but is not limited to, an electronic paper, a mobile phone, a tablet computer, a monitor, a laptop computer, a digital photo frame, a navigator, and any other products or components with a display function. It should be understood that the display apparatus has the same beneficial effects as the display substrate provided in embodiments described above.

Although some embodiments of the general inventive concept of the present disclosure have been shown and described, it will be understood by those skilled in the art that changes may be made to these embodiments without departing from the principles and spirit of the general inventive concept of the present disclosure, and the scope of the present disclosure is defined by the claims and their equivalents.

1. A display substrate, comprising:
a silicon-based base substrate comprising an active area and an edge area surrounding the active area;
a plurality of sub-pixels in the active area of the silicon-based base substrate, wherein the plurality of sub-pixels are arranged in an array in a first direction and a second direction, at least one of the plurality of sub-pixels comprises a pixel driving circuit and a light-emitting element, the pixel driving circuit is electrically connected to the light-emitting element and configured to drive the light-emitting element to emit light, and wherein the pixel driving circuit comprises a first transistor, the first transistor comprises a semiconductor layer, a gate, a source, and a drain;
an electronic device in the edge area of the silicon-based base substrate, wherein the electronic device comprises a second transistor, the second transistor comprises a semiconductor layer, a gate, a source and a drain, and the semiconductor layer, the gate, the source and the drain of the second transistor are arranged in same layers as the semiconductor layer, the gate, the source and the drain of the first transistor, respectively; and
a metal shielding portion in the edge area of the silicon-based base substrate, wherein the metal shielding portion is arranged in a fragmented manner on a side of each of the layers in which the semiconductor layer, the gate, the source and the drain of the second transistor are respectively located away from the silicon-based base substrate,
wherein an orthographic projection of the metal shielding portion on the silicon-based base substrate at least partially overlaps with an orthographic projection of the electronic device on the silicon-based base substrate.

2. The display substrate according to claim 1, wherein the orthographic projection of the metal shielding portion on the silicon-based base substrate covers the orthographic projection of the electronic device on the silicon-based base substrate.

3. The display substrate according to claim 1, further comprising n metal film layers, wherein the n metal film layers are arranged on a side of the layer in which the source of the electronic device and the drain of the electronic device are located away from the silicon-based base substrate, the n metal film layers are sequentially arranged away from the silicon-based base substrate, and n is a positive integer greater than or equal to 2; and
wherein the metal shielding portion comprises n metal shielding sub-portions, and the n metal shielding sub-portions are arranged in the n metal film layers, respectively.

4. The display substrate according to claim 3, further comprising n conductive connection portions located in the active area, wherein the n conductive connection portions are arranged in the n metal film layers, respectively, and each of the n metal shielding sub-portions is arranged in a same metal film layer as a respective one of the n conductive connection portions.

5. The display substrate according to claim 4, wherein the metal shielding portion comprises a plurality of metal shielding sub-portions arranged in a same metal film layer, and any two adjacent metal shielding sub-portions among the plurality of metal shielding sub-portions arranged in the same metal film layer are spaced apart from each other.

6. The display substrate according to claim 3, wherein an orthographic projection of the n metal shielding sub-portions on the silicon-based base substrate at least partially overlap with an orthographic projection of a same electronic device on the silicon-based base substrate; and
wherein an orthographic projection of one of any two of the n metal shielding sub-portions on the silicon-based base substrate coincides with an orthographic projection of the other of the any two of the n metal shielding sub-portions on the silicon-based base substrate.

7. The display substrate according to claim 3, wherein orthographic projections of at least two of the n metal shielding sub-portions on the silicon-based base substrate at least do not partially overlap with each other.

8. The display substrate according to claim 3, wherein the n metal shielding sub-portions comprise: a plurality of first metal shielding sub-portions arranged in an i^{th} metal film layer; and a plurality of second metal shielding sub-portions arranged in an (i+1)^{th} metal film layer, wherein i is a positive integer greater than or equal to 1 and less than or equal to (n−2); and
wherein orthographic projections of the plurality of first metal shielding sub-portions on the silicon-based base substrate and orthographic projections of the plurality of second metal shielding sub-portions on the silicon-based base substrate are alternately arranged in the first direction.

9. The display substrate according to claim 8, wherein the n metal shielding sub-portions further comprise a plurality of third metal shielding sub-portions arranged in an (i+2)^{th} metal film layer; and
wherein orthographic projections of the plurality of third metal shielding sub-portions on the silicon-based base substrate and the orthographic projections of the plurality of second metal shielding sub-portions on the silicon-based base substrate are alternately arranged in the first direction.

10. The display substrate according to claim 9, wherein an orthographic projection of at least one of the plurality of second metal shielding sub-portions on the silicon-based base substrate partially overlaps with an orthographic projection of an adjacent first metal shielding sub-portion among the plurality of first metal shielding sub-portions on the silicon-based base substrate or an orthographic projection of an adjacent third metal shielding sub-portion among the plurality of third metal shielding sub-portions on the silicon-based base substrate.

11. The display substrate according to claim 10, wherein the orthographic projections of the plurality of first metal shielding sub-portions on the silicon-based base substrate coincide with the orthographic projections of the plurality of third metal shielding sub-portions on the silicon-based base substrate, respectively.

12. The display substrate according to claim 1, further comprising m electronic devices and m metal shielding portions, wherein m is a positive integer greater than or equal to 2; and
wherein orthographic projections of the m metal shielding portions on the silicon-based base substrate cover orthographic projections of the m electronic devices on the silicon-based base substrate, respectively.

13. The display substrate according to claim 12, wherein orthographic projections of at least two adjacent metal shielding portions among the m metal shielding portions on the silicon-based base substrate are arranged at intervals in the first direction.

14. The display substrate according to claim 12, wherein orthographic projections of any two adjacent metal shielding portions among the m metal shielding portions on the silicon-based base substrate at least partially overlap with each other, such that the orthographic projections of the m metal shielding portions on the silicon-based base substrate extend continuously in the first direction.

15. The display substrate according to claim 3, wherein at least two of the n metal shielding sub-portions have different thicknesses; or
the n metal shielding sub-portions have a same thickness.

16. The display substrate according to claim 4, wherein among the n metal shielding sub-portions and the n conductive connection portions, the metal shielding sub-portion and the conductive connection portion arranged in the same metal film layer have a same thickness.

17. The display substrate according to claim 1, further comprising a plurality of bonding terminals arranged in the edge area of the silicon-based base substrate, wherein the orthographic projection of the metal shielding portion on the silicon-based base substrate is located between orthographic projections of the plurality of bonding terminals on the silicon-based base substrate and the active area.

18. The display substrate according to claim 17, wherein the metal shielding portion comprises a plurality of metal shielding sub-portions arranged in a same metal film layer as the plurality of bonding terminals, and a dimension of each of the plurality of metal shielding sub-portions arranged in the same metal film layer as the plurality of bonding terminals in the first direction is substantially equal to a dimension of a respective one of the plurality of bonding terminals in the first direction; and/or
a dimension of a gap between any two of the plurality of metal shielding sub-portions arranged in the same metal film layer as the plurality of bonding terminals in the first direction is substantially equal to a dimension of a gap between any two of the plurality of bonding terminals in the first direction; and/or
a dimension of each of the plurality of metal shielding sub-portions arranged in the same metal film layer as the plurality of bonding terminals in the second direction is less than a dimension of a respective one of the plurality of bonding terminals in the second direction; and/or
wherein at least one of the plurality of sub-pixels further comprises a reflective electrode, and a film layer in which the reflective electrode is located is arranged between a film layer in which the pixel driving circuit is located and a film layer in which the light-emitting element is located;
wherein the metal shielding portion further comprises a plurality of top-layer metal shielding sub-portions arranged in a same layer as the reflective electrode; and
wherein a dimension of each of the plurality of top-layer metal shielding sub-portions in the first direction is substantially equal to a dimension of a respective one of a plurality of reflective electrodes in the first direction; and/or a dimension of a gap between any two of the plurality of top-layer metal shielding sub-portions in the first direction is substantially equal to a dimension of a gap between any two of a plurality of reflective electrodes in the first direction.

19. (canceled)

20. The display substrate according to claim 9, wherein the (i+1)^{th} metal film layer is arranged on a side of the i^{th} metal film layer away from the silicon-based base substrate, and the (i+2)^{th} metal film layer is arranged on a side of the (i+1)^{th} metal film layer away from the silicon-based base substrate; and
wherein an edge of the second metal shielding sub-portion is indented towards a center of an electronic device corresponding to the first metal shielding sub-portion and the second metal shielding sub-portion with respect to an edge of the first metal shielding sub-portion, and an edge of the third metal shielding sub-portion is indented towards a center of an electronic device corresponding to the second metal shielding sub-portion and the third metal shielding sub-portion with respect to an edge of the second metal shielding sub-portion,
wherein a protrusion is provided at the edge of the first metal shielding sub-portion, such that a thickness of the first metal shielding sub-portion at the edge of the first metal shielding sub-portion is greater than a thickness of the first metal shielding sub-portion at a center of the first metal shielding sub-portion; and/or
wherein a protrusion is provided at the edge of the second metal shielding sub-portion, such that a thickness of the second metal shielding sub-portion at the edge of the second metal shielding sub-portion is greater than a thickness of the second metal shielding sub-portion at a center of the second metal shielding sub-portion,
wherein a cross-section of the protrusion perpendicular to an upper surface of the silicon-based base substrate and a cross-section of a conductive connection portion arranged in a same layer as the protrusion perpendicular to the upper surface of the silicon-based base substrate have a same shape,
wherein the n metal shielding sub-portions further comprise a fourth metal shielding sub-portion arranged in a j^{th} metal film layer, and j is a positive integer greater than 1 and less than n;
wherein the pixel driving circuit further comprises a capacitor, at least one electrode plate of the capacitor is arranged in the j^{th} metal film layer; and
wherein a thickness of the fourth metal shield sub-portion is less than a thickness of any one of the first metal shield sub-portion, the second metal shield sub-portion, and the third metal shield sub-portion; and/or
wherein the electronic device comprises a memory cell, and the memory cell comprises a pair of transistors arranged on the silicon-based base substrate and electrically connected to each other in series; and
wherein the orthographic projection of the metal shielding portion on the silicon-based base substrate covers orthographic projections of the pair of transistors on the silicon-based base substrate; and/or
wherein a sum of thicknesses of the n metal shielding sub-portions meets:
$$H \geq \sqrt{\frac{2}{ω μ σ}} ,$$
wherein δ and ω are respectively a penetration depth and a frequency of radiation rays irradiated on the metal shielding portion, μ and σ are respectively a magnetic conductivity of the metal shielding portion and an electrical conductivity of the metal shielding portion, and H is the sum of the thicknesses of the n metal shielding sub-portions.

21. (canceled)

22. (canceled)

23. (canceled)

24. (canceled)

25. (canceled)

26. A display apparatus, comprising the display substrate according to claim 1.
